(19) United States
(12) Patent Application Publication
(10) Pub. No.: US 2005/0215075 A1
(43) Pub. Date: Sep. 29, 2005

(54) Integrated photochemical treatment of gases

(76) Inventor: Emmanuelle Veran, Aix Les Bains (FR)

Correspondence Address: SUGHRUE MION, PLLC, 2100 PENNSYLVANIA AVENUE, N.W., SUITE 800, WASHINGTON, DC, 20037, US

(21) Appl. No.: 10/515,251

(22) PCT Filed: May 30, 2003
(86) PCT No.: PCT/FR03/01635

§ 371 Date: Nov. 19, 2004

(30) Foreign Application Priority Data
May 30, 2002 (FR) 02/06629

(51) Int. Cl. H01L 21/469

(52) U.S. Cl. 438/788

(57) ABSTRACT

According to the invention, at least one excimer lamp (7) is placed at the outlet from a treatment or process chamber (9), the lamp producing radiation in the far ultraviolet in the stream (10) of gaseous effluent to cause dissociation thereof by photochemical reaction. Thus, the vapors and gases containing specifically solvents such as isopropyl alcohol, acetone, or N-methyl-pyrrolidone, are dissociated into carbon dioxide gas and water or other elements without any need for dilution, and in a device that is small in size and easily integratable.

### TECHNICAL FIELD OF THE INVENTION

The invention relates to processes in the semiconductor industry in which semiconductor wafers are machined and treated in process and treatment chambers.

Such processes include in particular steps of applying a photoresist layer, steps of developing the photoresist layer, and steps of etching or depositing on zones of substrates that are not covered by a mask.

Those various steps are performed in process and treatment chambers which are connected to pump means to extract the treatment vapors or gases and the residue gases.

In such processes, certain steps consist in particular in eliminating the photoresist layers in stripping chambers.

In semiconductor industry processes, certain process steps, in particular steps of applying a layer of a photoresist based on a solvent, steps of developing the photoresist layer, steps of subsequently eliminating photoresist layers (i.e. stripping), and deposition steps using metal-organic compositions (metal-organic chemical vapor deposition (MOCVD)), lead to effluents being given off that contain solvent vapors.

Such vapors and gases contain in particular solvents such as isopropyl alcohol, acetone, and N-menthyl pyrrolidone.

Those vapors and gases are pumped by the pump means and they must be treated before being exhausted to the atmosphere.

At present, the treatment of the vapors and gases extracted from stripping chambers or enclosures for metal-organic deposition consist in washing the vapors and gases in a washing tower, so that the effluent can subsequently be treated in liquid form.

In a washing tower, the stream of effluent is directed upwards against a stream of sprayed dilution liquid traveling downwards. The liquid dissolves the vapors and gases for subsequent treatment.

The vertical size of a washing tower must be sufficient to enable the droplets of liquid and the vapors and gases to be present together for sufficient time for dissolution to occur.

This results in gas treatment installations that are relatively bulky, that are impossible to integrate in the proximity of stripping enclosures and process chambers, and that are in particular too tall to be integrated in the false floor of a clean room containing the process and treatment chambers.

Another drawback of known installations is that the effluents are treated after they have been diluted, thereby reducing the effectiveness of the treatment.

In fields of application other than semiconductors, proposals have already been made, e.g. in document JP 2000/079322 A, to depollute solvent gases by causing them to pass through an enclosure for treating the gases by vacuum ultra violet (VUV) followed by a biomembrane reactor having means for maintaining the biomembrane moist. A fan serves to recirculate the gases from the outlet of the reactor back to the inlet of the VUV treatment enclosure. The gas is treated at atmospheric pressure. That document contains no suggestion for an application to semiconductor fabrication, and the device would not be suitable for such an application because of the excessive size that results from the presence of the biomembrane reactor.

In the field of treating liquids such as water extracted from the ground, document DE 297 07 912 U teaches spraying water in a washing tower with a counterflow of air. The air is then treated in an air treatment installation having excimer ultraviolet emitters and including an installation for washing with soda.

The devices described in the above documents are complex and bulky and they are therefore not suitable for solving the problem of being integrated in the proximity of stripping enclosures or of process chambers.

Document DE 43 07 204 A describes an apparatus for decontaminating liquids and/or gases in a continuous stream reactor using an excimer laser type ultraviolet light source. The fluid which flows through the reactor is exposed to the laser light which passes through a window. No suggestion is made of an application to semiconductor fabrication, nor to the use of excimer lamps.

### SUMMARY OF THE INVENTION

The invention seeks to avoid the drawbacks of prior art systems in the field of semiconductor fabrication, in particular by making it possible very significantly to reduce the size of effluent treatment units, while also providing more effective treatment of the effluent.

Thus, it is desirable to limit the floor area occupied, to reduce the risks of the installation becoming polluted, and to improve the treatment of effluent.

To achieve these objects, and others, the essential idea of the invention is to perform at least partial treatment of the vapors and gases as they leave stripping chambers, metal-organic deposition chambers, and more generally process chambers, in which processes occur that give off effluents containing solvent vapors, by subjecting the effluent to irradiation in the far ultraviolet.

Thus, the invention provides a device for machining or treating semiconductor wafers, the device comprising a treatment or process chamber connected by a pipe to pump means for extracting the treatment vapors or gases and the residue gases, and in which one or more excimer lamps produce radiation in the far ultraviolet in the stream of treatment vapors or gases and residue gases in the proximity of the treatment or process chamber.

The excimer lamps may be placed in the stream of vapors or gases upstream from the pump means. When the pump means comprise a primary pump and a secondary pump, the excimer lamps may be placed in the stream of vapors or gases upstream from the primary pump and/or upstream from the secondary pump.

In a first embodiment, the excimer lamp(s) is/are placed in a specific treatment chamber.

In a second embodiment, the excimer lamp(s) is/are placed in the pipe for extracting the vapors and gases from a treatment or process chamber.

In a third embodiment, the excimer lamp(s) is/are placed around the pipe for extracting the vapors and gases from a treatment or process chamber.

Excimers are complexes of atoms or molecules in the excited state which, under normal conditions, do not possess a stable fundamental state. Typical examples are constituted by associations between two rare gas atoms, e.g. XeXe, ArAr, or an electronically-excited molecular association between a rare gas atom and a halogen atom, e.g. XeCl. In which case, the molecule is known as an exciplex molecule. Nevertheless, in order to be more general, the invention makes use of the general term excimer to designate both excimers and exciplexes.

Preferably, for the intended applications of the invention, the lamp(s) produce irradiation at a wavelength lying in the range about 100 nanometers (nm) to 200 nm.

Good results have been obtained with lamps comprising at least one XeXe type excimer lamp.

Advantageously, provision can be made for the excimer lamp to be tubular in shape, emitting into its outside space which itself conveys the flow of gaseous effluent.

The device preferably further comprises means for injecting oxygen in the form of gaseous oxygen or water vapor into the stream of vapors or gases upstream from the excimer lamps.

The invention also provides a method of treating effluent of the solvent vapor type coming from semiconductor fabrication processes, including a prior step of treating the vapors or gases by photochemical reaction by means of radiation in the far ultraviolet as soon as possible after the vapors or gases have left a treatment or process chamber.

The irradiation may advantageously be provided by one or more XeXe type excimer lamps.

Preferably, oxygen in the form of gaseous oxygen or water vapor is injected into the vapors or gases for treatment upstream from the radiation in the far ultraviolet.

Adding oxygen or water vapor makes it possible to provide better treatment of the effluents than is usually encountered in semiconductor fabrication processes. This addition makes it possible, by oxidation, to combine with the radicals that result from the dissociation by the photochemical treatment. Otherwise the radicals could under certain circumstances recombine with one another, so that the treatment would be insufficient. In this respect, provision could be made to add oxygen, or water vapor, or some other oxygen-containing substance.

### BRIEF DESCRIPTION OF THE DRAWINGS

Other objects, characteristics, and advantages of the present invention appear from the following description of particular embodiments given with reference to the accompanying figures, in which:

FIG. 1 is a side view in section in the form of a theoretical diagram of an excimer lamp of cylindrical shape;

FIG. 2 is a diagrammatic side view of an effluent treatment system in an embodiment of the present invention;

FIG. 3 is a diagrammatic side view of an effluent treatment system in a second embodiment of the present invention;

FIG. 4 is a cross-section on plane A-A in FIG. 3; and

FIG. 5 is a diagrammatic view of a device for machining or treating semiconductor wafers in another embodiment of the invention.

### DESCRIPTION OF PREFERRED EMBODIMENTS

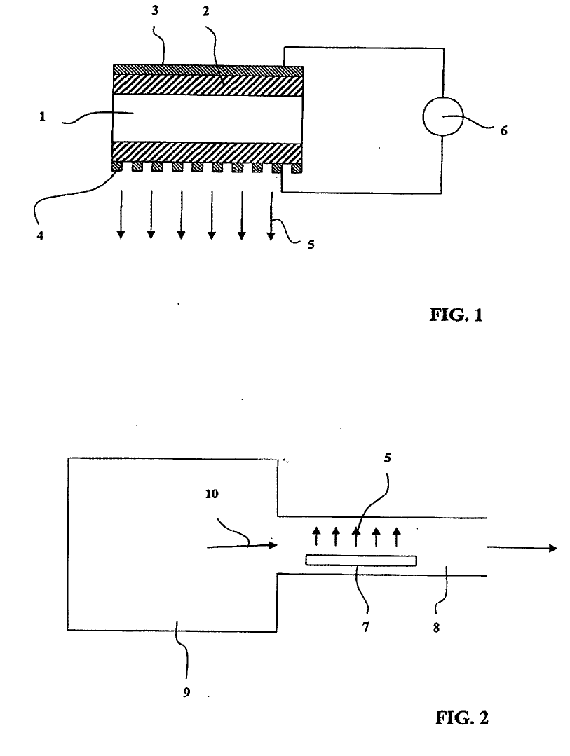

FIG. 1 is a theoretical diagram of an excimer lamp of cylindrical shape. A discharge space 1 is constituted inside a quartz tube 2 whose outside surface is metal-coated so as to constitute two electrodes 3 and 4. The electrode 4 is in the form of a grid so as to allow radiation 5 to pass through. The electrodes 3 and 4 are biased by a suitable generator 6.

In FIG. 2, one or more excimer lamps 7 can be placed in the pipes 8 for extracting vapors and gases from a treatment or process chamber 9, and they generate radiation 5 in the stream 10 of gaseous effluent, which radiation causes the solvent vapors and gases to decompose into carbon dioxide gas and water or other elements.

The nature of the excimer lamp 7 can be selected as a function of the vapors and gases to be treated. It is found that an XeXe type excimer lamp gives excellent results at a wavelength of about 172 nm for the vapors and gases that are usually produced by processes in the semiconductor industry.

By positioning the excimer lamps 7 close to the treatment or process chamber 9 that produces the stream 10 of vapors or gases to be treated, the vapors and gases are treated before they are diluted, and before they have had time to produce deposits on the pipes 8 for extracting the vapors and gases.

The shape of the reactor can be adjusted to improve the effectiveness and the integration of the system. For example, in FIG. 2, the excimer lamp is a tubular lamp that emits outwards.

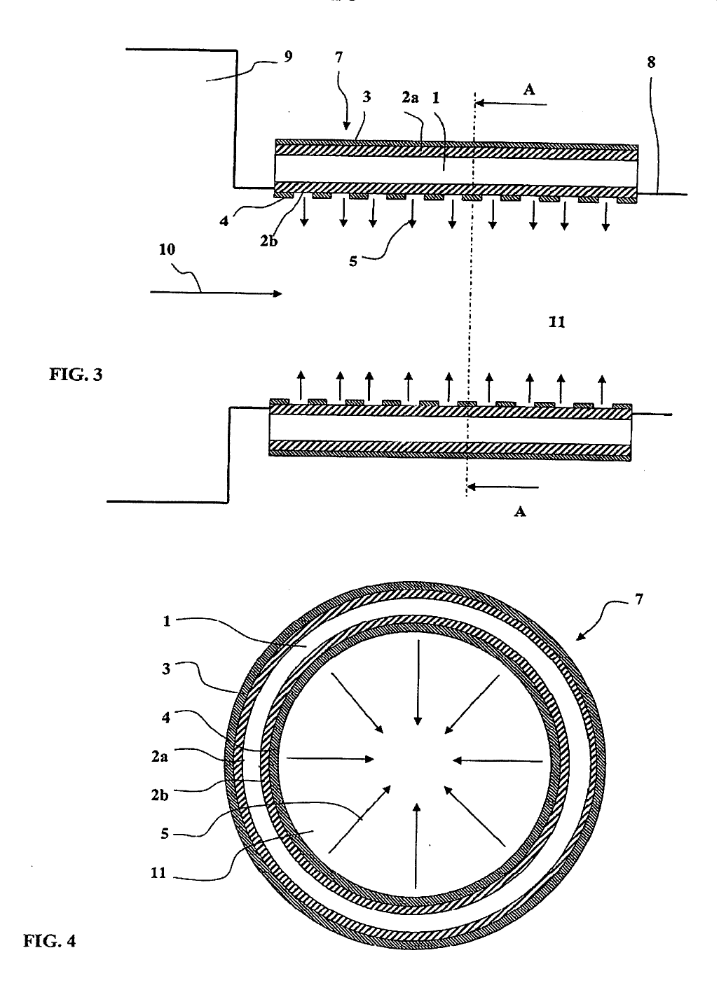

In FIGS. 3 and 4, the excimer lamp is a tubular lamp that emits into its own inside space 11. The discharge space 1 is situated between two concentric quartz tubes 2a and 2b, with the electrode 3 on the outside surface of the outer quartz 2a, and with the grid-shaped electrode 4 on the inside surface of the inner quartz 2b. Thus, the stream 10 of gaseous effluent flows directly within the inside space 11 of the excimer lamp 7, and is subjected to the radiation 5 which causes it to decompose into carbon dioxide gas and water or other elements.

The excimer lamp(s) 7 can be placed in a specific treatment chamber, or they can merely be placed in or around a pipe 8 for extracting the vapors and gases.

Radiation at a wavelength lying in the range 100 nm to 200 nm approximately is advantageous since it enables a satisfactory dissociation rate to be obtained of the vapors and gases without the presence of a catalyst.

The photochemical treatment performed by the present invention is advantageous in the sense that it makes use of no external reagent that is particularly expensive, dangerous, and/or toxic, such as perfluoro carbons (PFCs) and NF₃.

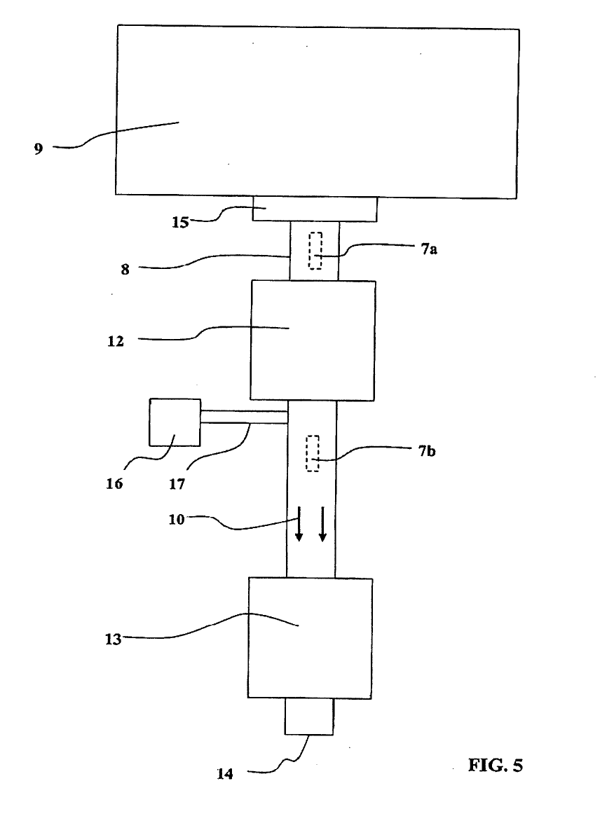

FIG. 5 is a diagram showing the general structure of a device for machining or treating semiconductor wafers in an embodiment of the present invention. The device comprises a treatment or process chamber 9 connected by a pipe 8 to pump means comprising, for example: a primary pump 13 and a secondary pump 12 connected in series one behind the other in order to extract the treatment vapors and gases and the residue gases from the chamber 9 and in order to deliver them via a delivery orifice 14. The stream of treatment vapors and gases and of residue gases flows along the entire vacuum line constituted by the pipe 8 and the pumps 12 and 13. A control or isolation valve 15 is generally interposed between the treatment or process chamber 9 and the inlet to the pipe 8.

The figure shows the positioning of the excimer lamps 7b in the stream 10 of vapors or gases upstream from the primary pump 13.

The figure also shows excimer lamps 7a placed in the stream 10 of vapors or gases upstream from the secondary pump 12.

In unexpected manner, the photochemical treatment of the gases is effective even under the low pressure conditions that exist in the pipe 8, not only upstream from the primary pump 13, but also upstream from the secondary pump 12.

Better treatment effectiveness is obtained by providing means for injecting oxygen in the form of gaseous oxygen, or of an oxygen containing compound such as water vapor, into the stream 10 of vapors or gases upstream from the excimer lamp. For example, FIG. 5 shows an oxygen source 16 which introduces gaseous oxygen via an oxygen insertion pipe 17 upstream from the excimer lamp 7b.

The present invention is not limited to the embodiments described explicitly above, and it includes the various generalizations and variants that are within the competence of the person skilled in the art.

1. A device for machining or treating semiconductor wafers, the device comprising a treatment or process chamber (9) connected by a pipe (8) to pump means (12, 13) for extracting the treatment vapors or gases and the residue gases, the device being characterized in that it comprises one or more excimer lamps (7, 7a, 7b) which produce radiation in the far ultraviolet in the stream (10) of treatment vapors or gases and residue gases in the proximity of the treatment or process chamber (9).

2. A device according to claim 1, characterized in that excimer lamps (7b) are placed in the vapor or gas stream (10) upstream from a primary pump (13).

3. A device according to claim 1, characterized in that excimer lamps (7a) are placed in the vapor or gas stream (10) upstream from a secondary pump (12).

4. A device according to claim 1, characterized in that the excimer lamp(s) (7) is/are placed in a specific treatment chamber.

5. A device according to claim 1, characterized in that the excimer lamp(s) (7, 7a, 7b) is/are placed in the pipe (8) for extracting vapors and gases from a treatment or process chamber (9).

6. A device according to claim 1, characterized in that the excimer lamp(s) (7) is/are placed around the pipe (8) for extracting vapors and gases from a treatment or process chamber (9).

7. A device according to claim 1, characterized in that the excimer lamp(s) (7, 7a, 7b) produce radiation at a wavelength lying in the range about 100 nm to about 200 nm.

8. A device according to claim 1, comprising at least one excimer lamp (7) of XeXe type.

9. A device according to claim 1, in which the excimer lamp (7) is tubular in shape, emitting into its external space conveying the stream (10) of gaseous effluent.

10. A device according to claim 1, characterized in that it further comprises means (16, 17) for injecting oxygen in the form of gaseous oxygen or water vapor into the stream (10) of vapors or gases upstream from the excimer lamps (7, 7a, 7b).

11. A method of treating effluents of the solvent vapor type coming from semiconductor fabrication processes, the method being characterized in that it includes a prior step of treating the vapors or gases by photochemical reaction by means of radiation in the far ultraviolet as soon as possible after the vapors or gases have left a treatment or process chamber (9).

12. A method according to claim 11, characterized in that the irradiation is performed by one or more excimer lamps (7) of XeXe type.

13. A method according to claim 11, characterized in that oxygen is injected in the form of gaseous oxygen or water vapor into the vapors or gases for treatment upstream from the far ultraviolet radiation.
